(19) United States
(12) Patent Application Publication
(10) Pub. No.: US 2009/0152568 A1
(43) Pub. Date: Jun. 18, 2009

(54) Method for packaging submount adhering light emitting diode and package structure thereof

(75) Inventors: Jian-An Lu, Kaohsiung (TW); Yen-Ting Pan, Kaohsiung (TW)

Correspondence Address: TROXELL LAW OFFICE PLLC, SUITE 1404, 5205 LEESBURG PIKE, FALLS CHURCH, VA, 22041, US

(73) Assignee: International Semiconductor Technology Ltd., Kaohsiung (TW)

(21) Appl. No.: 12/000,657

(22) Filed: Dec. 14, 2007

(51) Int. Cl. H01L 33/00

(52) U.S. Cl. 257/88; 438/27; 257/E33.058

(57) ABSTRACT

A method for packaging submount adhering LED comprises providing a first substrate which has an upper surface, a lower surface forming a plurality of heat-dissipating cavities and a plurality of die-attaching regions defined on the upper surface. Each of the heat-dissipating cavities corresponds to the die-attaching region and has a bottom surface, wherein there is a carrier base located between the bottom surface and the die-attaching region. Next, a heat conductor is formed in the heat-dissipating cavity and a plurality of LEDs are disposed on the die-attaching regions of the first substrate. Then, a second substrate is provided which has a first surface facing to the upper surface of the first substrate, a second surface opposite to the first surface and a plurality of reflective slots communicating with the first and second surfaces. Each of the reflective slots corresponds to the LED and the die-attaching region and couples the first and second substrates thereby allowing each of the LEDs to be located in the reflective slot.

### FIELD OF THE INVENTION

The present invention relates generally to a method for packaging LED (light emitting diode) and package thereof and, more particularly, to a method for packaging submount adhering LED and package structure thereof.

### BACKGROUND OF THE INVENTION

It is known that most packaging method of LED is to fix LED die on a submount which forms reflective groove surface beforehand, however, since size of the reflective groove surface is frequently formed too small, fixation of LED die becomes difficult to increase packaging cost in case of practical mass-production. Besides, the submount also serves as heat-dissipation for LED but cannot provide a high heat-dissipating efficiency, which easily results in decreasing light emitting efficiency or damaging due to overheat of LED.

### SUMMARY OF THE INVENTION

The primary object of the present invention is to provide a method for packaging submount adhering LED and package structure thereof. The packaging method includes providing a first substrate having an upper surface, a lower surface opposite to the upper surface and a plurality of die-attaching regions defined on the upper surface. Next, forming a plurality of heat-dissipating cavities on the lower surface of the first substrate, wherein each of the heat-dissipating cavities corresponds to the die-attaching region and has a bottom surface, there is a carrier base located between the bottom surface and the die-attaching region. Next, forming a heat conductor in each of the heat-dissipating cavities and disposing a plurality of LEDs on the die-attaching regions of the first substrate. Then, providing a second substrate having a first surface facing to the upper surface of the first substrate, a second surface opposite to the first surface and a plurality of reflective slots communicating with the first and second surfaces, each of the reflective slots corresponds to the LED and the die-attaching region. Finally, coupling the second substrate to the first substrate thereby allowing each of the LEDs to be located in the reflective slot. In accordance with the present invention, the difficulty of packaging submount adhering LED is improved effectively, the heat-dissipating efficiency of submount for LED is increased practically as well as the LEDs are able to form a line light source by means of optical action of the reflective slots, wherein the line light source may be used for replacing the known CCFL (cold cathode fluorescent lamp) which is frequently utilized by LCD (liquid crystal display).

### DESCRIPTION OF THE DRAWINGS

FIG. 1A to FIG. 1E is a flow diagram illustrating the method for packaging a submount adhering LED in accordance with a preferred embodiment of the present invention.

FIG. 2A taken along line A-A of FIG. 1A is a sectional view illustrating fabricating process of providing a first substrate.

FIG. 2B taken along line B-B of FIG. 1B is a sectional view illustrating fabricating process of forming a plurality of heat-dissipating cavities.

FIG. 2C taken along line C-C of FIG. 1C is a sectional view illustrating fabricating process of forming a heat conductor in each of the heat-dissipating cavities.

FIG. 2D taken along line D-D of FIG. 1D is a sectional view illustrating fabricating process of disposing a plurality of LEDs on the first substrate.

FIG. 2E is a sectional view illustrating fabricating process of providing a second substrate.

FIG. 2F taken along line E-E of FIG. 1E is a sectional view illustrating fabricating process of coupling the second substrate to the first substrate.

FIG. 3A to 3C is a flow diagram illustrating the method of applying through hole and heat conductor to increase heat-dissipating speed of LED in accordance with a preferred embodiment of the present invention.

FIG. 4A taken along line F-F of FIG. 3A is a sectional view illustrating fabricating process of forming through hole on the carrier base.

FIG. 4B taken along line G-G of FIG. 3B is a sectional view illustrating fabricating process of forming heat conductor in the through hole.

FIG. 4C taken along line H-H of FIG. 3C is a sectional view illustrating fabricating process which the heat conductor touches the LED.

FIG. 5 illustrates the structure of forming a Ti layer and an Au layer on upper surface of the first substrate in accordance with a preferred embodiment of the present invention.

FIG. 6A to 6C is a flow diagram illustrating the method of directly disposing LED on the heat conductor in accordance with another embodiment of the present invention.

FIG. 7 illustrates a package including submount adhering LED in accordance with a preferred embodiment of the present invention.

### DETAILED DESCRIPTION OF THE INVENTION

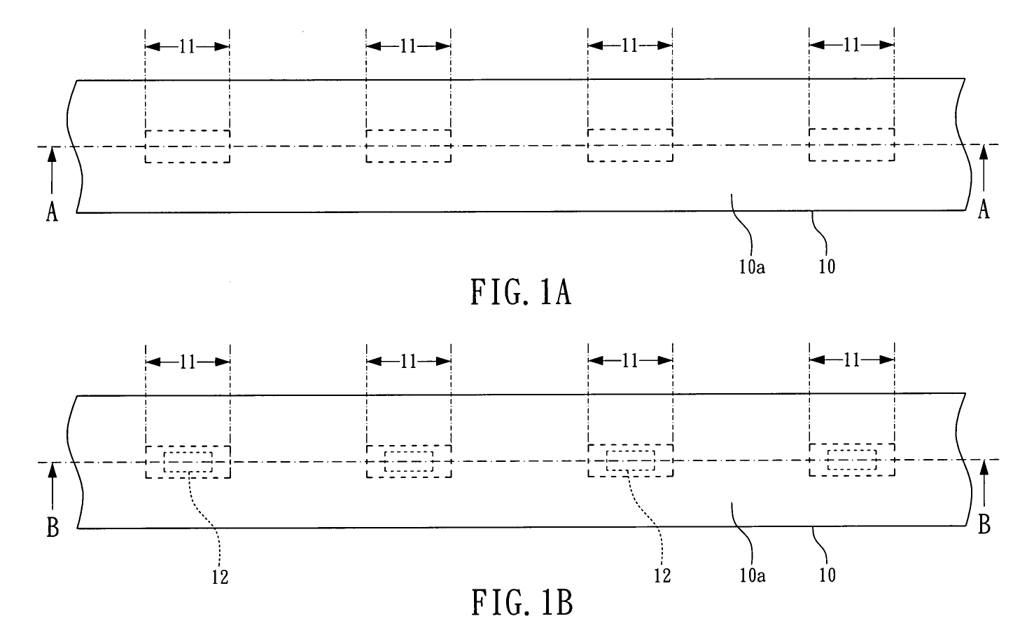

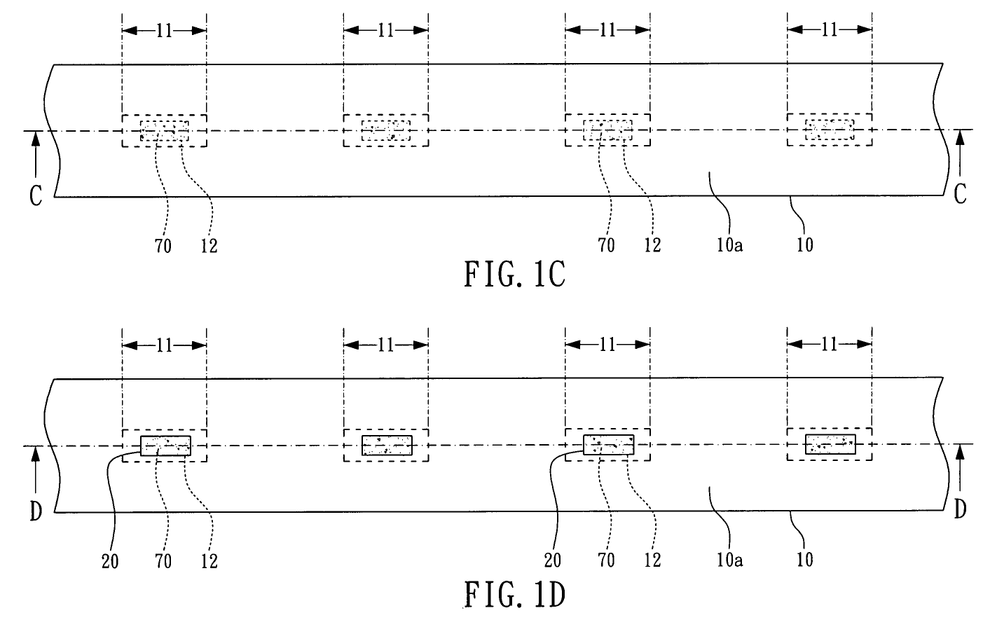

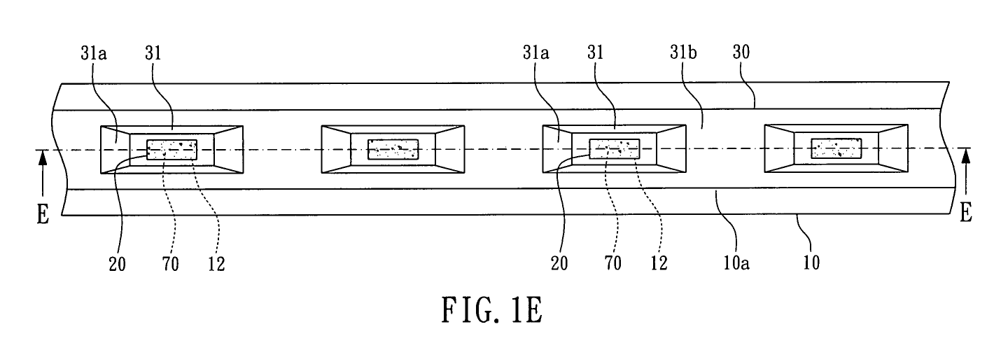

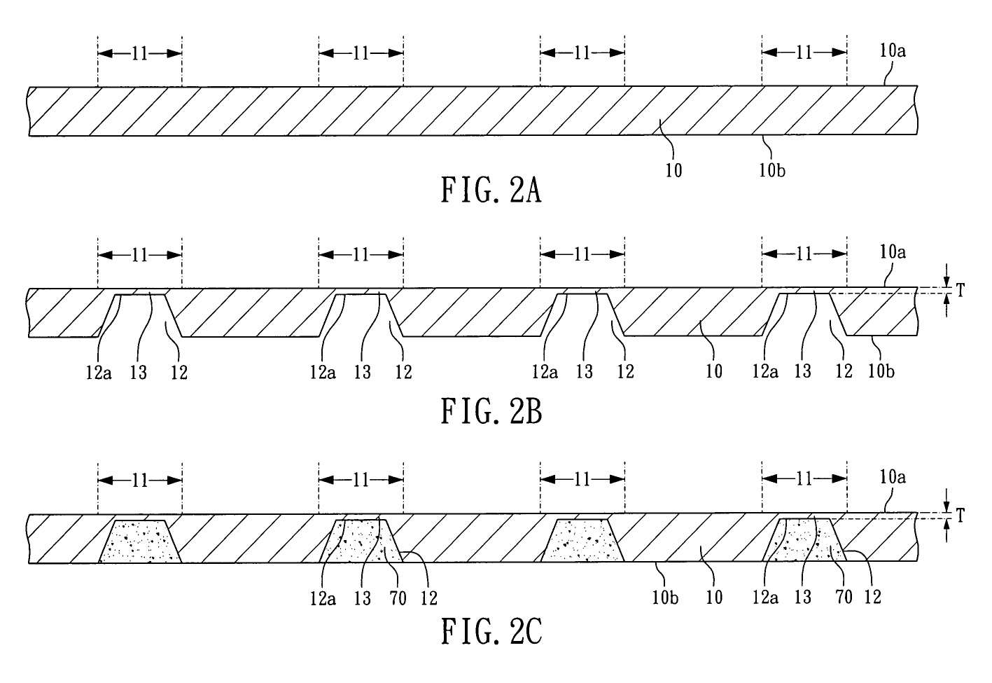

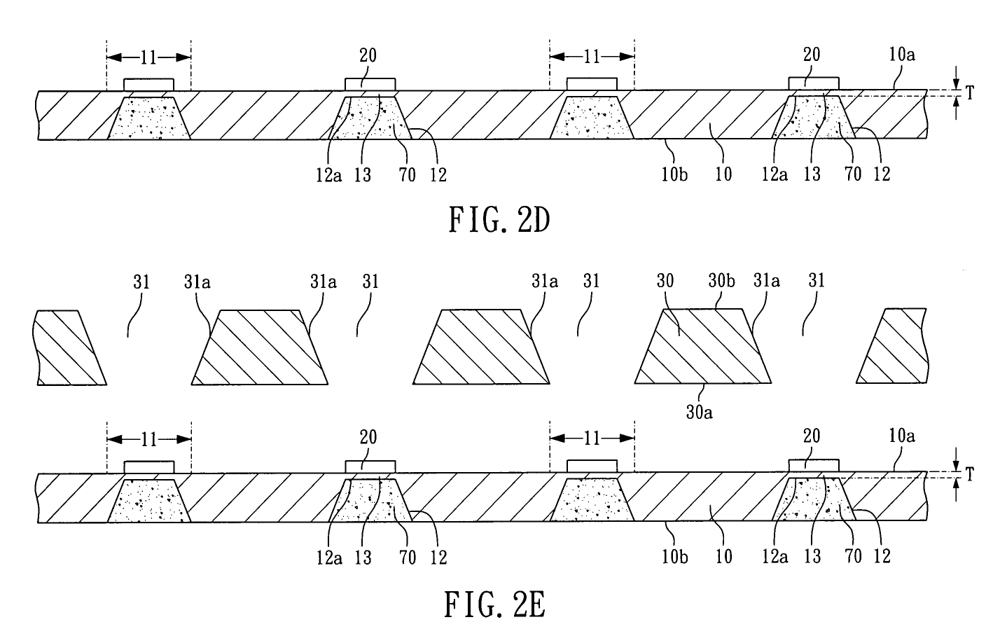

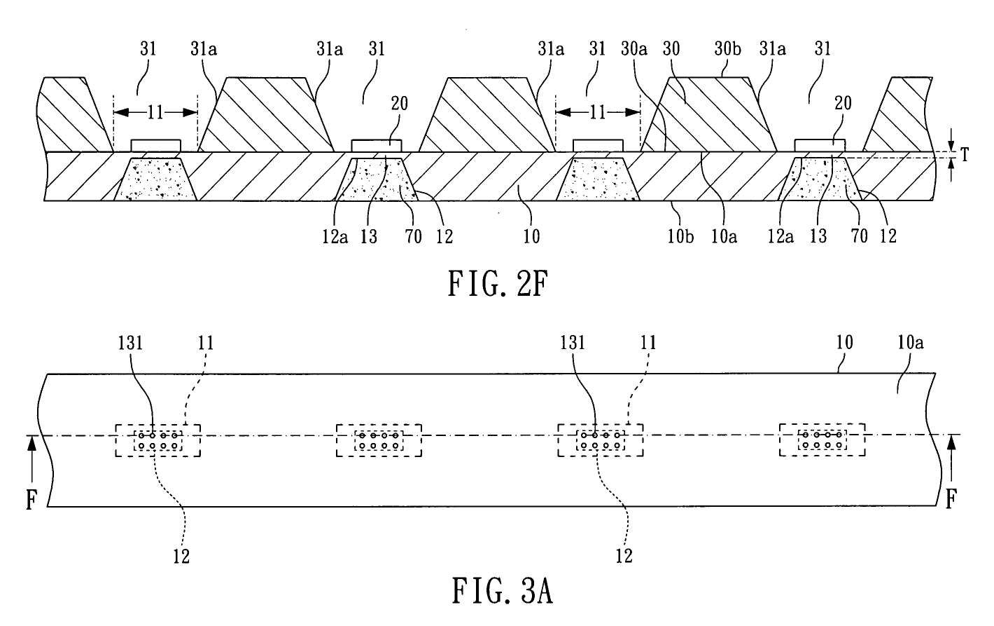

With reference to FIG. 1A to 1E and FIG. 2A to 2F, a method for packaging submount adhering LED comprising several steps in accordance with a preferred embodiment of the present invention is described in detail with the accompanying drawings as follows. Initially, with reference to FIG. 1A and FIG. 2A, a first substrate 10 is provided, which is a silicon substrate and has an upper surface 10a, a lower surface 10b opposite to the upper surface 10a and a plurality of die-attaching regions 11 defined on the upper surface 10a. Next, with reference to FIG. 1B and FIG. 2B, a plurality of heat-dissipating cavities 12 are formed on the lower surface 10b of the first substrate 10 by etching method, each of the heat-dissipating cavities 12 corresponds to the die-attaching region 11 and has a bottom surface 12a, wherein there is a carrier base 13 located between the bottom surface 12a and the die-attaching region 11, besides the carrier base 13 has a thickness T within a range of 10 to 50 micron in this embodiment. Next, with reference to FIG. 1C and FIG. 2C, a heat conductor 70 is formed in each of the heat-dissipating cavities 12 by electroplating method, wherein the heat conductor 70 may be made of copper or silver in this embodiment. Next, with reference to FIG. 1D and FIG. 2D, a plurality of LEDs 20 are disposed on the die-attaching regions 11 of the first substrate 10 and each of them is disposed on the carrier base 13. In this embodiment, each of the carrier bases 13 may be applied for supporting the LED 20 and conducting the heat generated from the LED 20 to the heat conductor 70, and subsequently to exterior for heat-dissipation. Preferably, the LEDs 20 are arranged in alignment. Next, with reference to FIG. 2E, a second substrate 30 is provided, which is a silicon substrate and has a first surface 30a facing to the upper surface 10a of the first substrate 10, a second surface 30b opposite to the first surface 30a and a plurality of reflective slots 31 communicating with the first and the second surfaces 30a, 30b. In this embodiment, each of the reflective slots 31 having a photo-reflecting surface 31a is trapezoid in shape and corresponds to the LED 20 and the die-attaching region 11. Finally, with reference to FIG. 1E and FIG. 2F, the second substrate 30 is coupled to the first substrate 10 thereby allowing each of the LEDs 20 to be located in the reflective slot 31, and meantime each of the photo-reflecting surfaces 31a faces to the LED 20 as to reflect the light emitted from the LED 20. In this embodiment, the second substrate 30 is coupled to the upper surface 10a of the first substrate 10 by either adhering method or metal eutectic method.

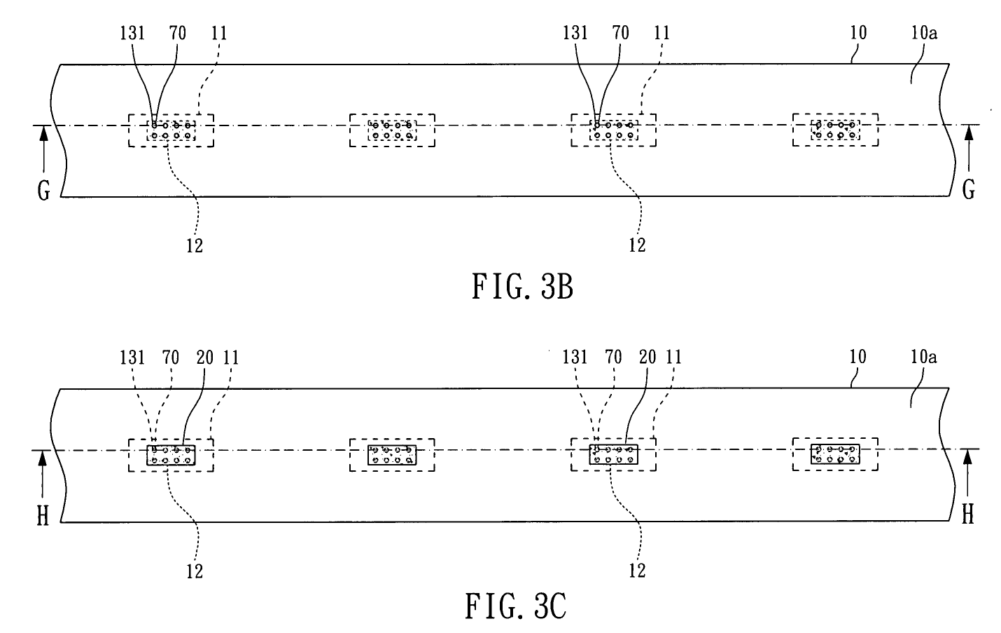

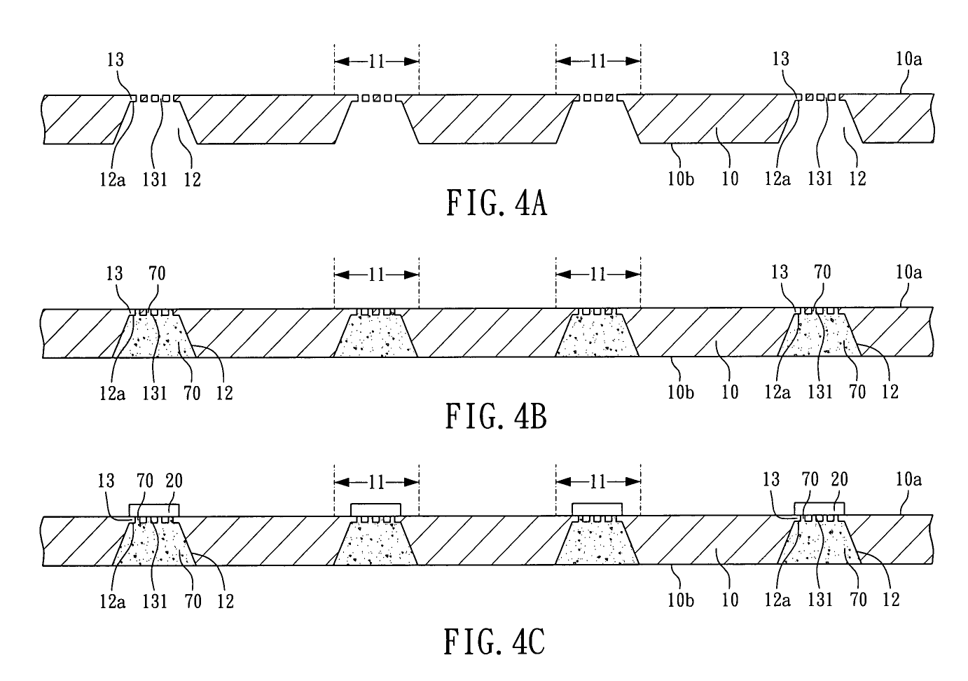

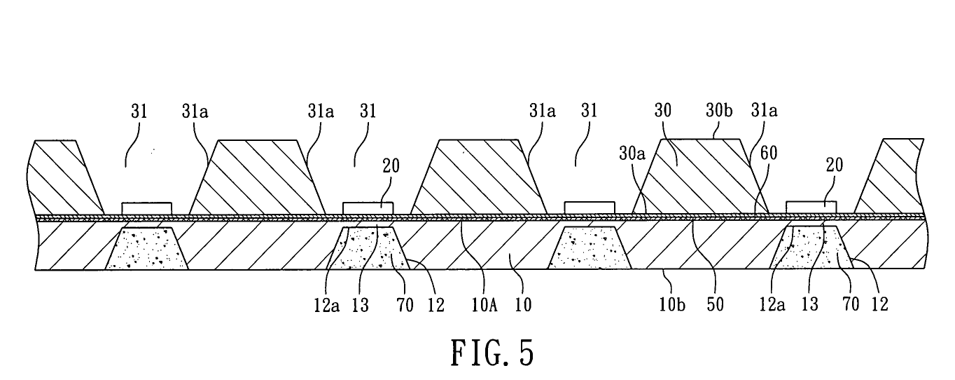

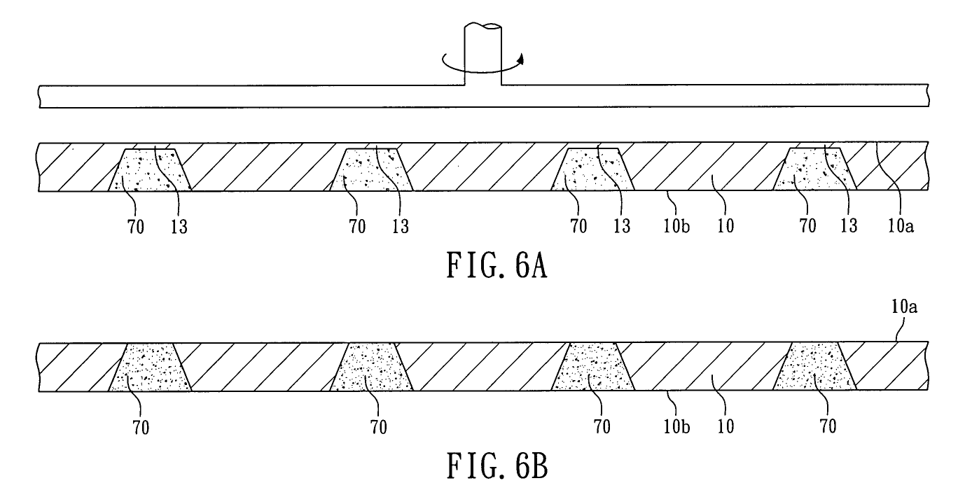

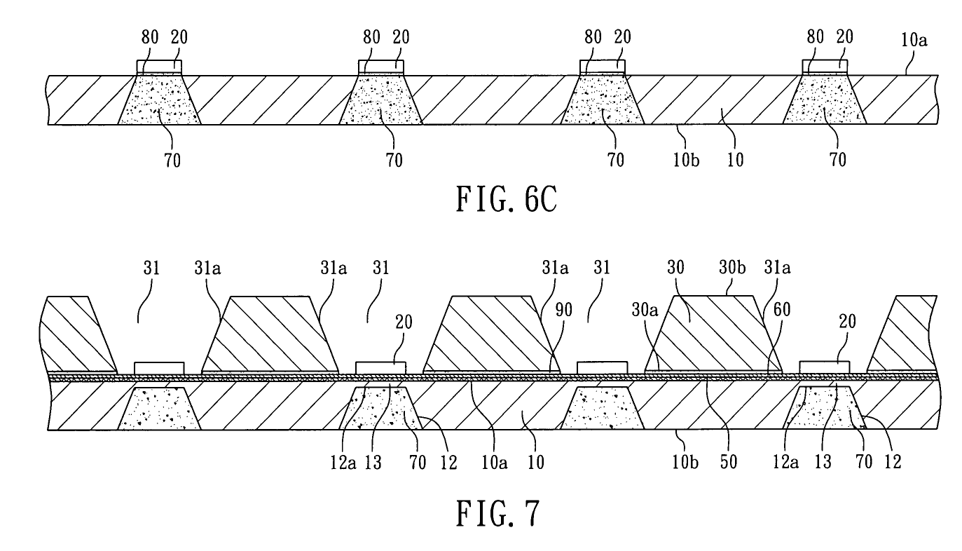

For the purpose to further increase heat-dissipating speed of the LED 20, several steps are provided in this embodiment and described in detail with the accompanying drawings as follows. Initially, with reference to FIG. 3A and FIG. 4A, at least one through hole 131 is formed on the carrier base 13 of the first substrate 10 to communicate with the die-attaching region 11 of the first substrate 10 and the bottom surface 12a of the heat-dissipating cavity 12. Next, with reference to FIG. 3B and FIG. 4B, each of the heat conductors 70 may further be formed in the through hole 131 of each of the carrier bases 13. Next, with reference to FIG. 3C and FIG. 4C, when the LEDs 20 are disposed on the carrier bases 13 respectively, each of the heat conductors 70 is directly able to touch the LED 20, which enables the heat generated from the LED 20 to be directly conducted to exterior via the heat conductor 70 for rapid heat-dissipation. In another embodiment with reference to FIG. 5, it may further form a Ti layer 50 on the upper surface 10a of the first substrate 10 and then an Au layer 60 on the Ti layer 50 beforehand to increase heat-dissipating efficiency of submount for LED, since the Ti layer 50 and the Au layer 60 are the material with high thermal conductive coefficient suitable for heat-dissipation. Otherwise, in further another embodiment with reference to FIG. 6A to 6C, there is another method to effectively carry out heat-dissipation. With reference to FIG. 6A, a step of polishing the upper surface 10a of the first substrate 10 is executed prior to disposing the LEDs 20 on the die-attaching regions 12 of the first substrate 10 so as to remove the carrier bases 13 and expose the heat conductors 70 on the upper surface 10a with reference to FIG. 6B. Next, each of the LEDs 20 is fixed on the heat conductor 70 with reference to FIG. 6C and a metal solder layer 80 formed between the LED 20 and the heat conductor 70 is used for fixing the LED 20 on the heat conductor 70 in this embodiment, such that the heat generated from the LED 20 can be conducted to exterior via the metal solder layer 80 and the heat conductor 70 for rapid heat-dissipation.

The package structure formed by the packaging method of the present invention, with reference again to FIG. 1E and FIG. 2F, comprises a first substrate 10, a plurality of heat conductors 70, a plurality of LEDs 20 and a second substrate 30. The first substrate 10 is a silicon substrate and has an upper surface 10a, a lower surface 10b opposite to the upper surface 10a and a plurality of die-attaching regions 11 defined on the upper surface 10a. The lower surface 10b has a plurality of heat-dissipating cavities 12 formed thereon, each of the heat-dissipating cavities 12 corresponds to the die-attaching region 11 and has a bottom surface 12a, wherein there is a carrier base 13 located between the bottom surface 12a and the die-attaching region 11, besides the carrier base 13 has a thickness T within a range of 10 to 50 micron in this embodiment. The heat conductors 70 are formed in the heat-dissipating cavities 12 respectively by electroplating method, wherein the heat conductor 70 may be made of copper or silver in this embodiment. The LEDs 20 are disposed on the die-attaching regions 11 of the first substrate 10 respectively and each of them is disposed on the carrier base 13. In this embodiment, each of the carrier bases 13 may be applied for supporting the LED 20 and conducting the heat generated from the LED 20 to the heat conductor 70, and subsequently to exterior for heat-dissipation. Besides, it is preferable to arrange the LEDs 20 in alignment. The second substrate 30 is coupled to the upper surface 10a of the first substrate 10 and has a first surface 30a facing to the upper surface 10a of the first substrate 10, a second surface 30b opposite to the first surface 30a and a plurality of reflective slots 31 communicating with the first and second surfaces 30a, 30b. Each of the reflective slots 31 having a photo-reflecting surface 31a is trapezoid in shape and corresponds to the LED 20 and the die-attaching region 11. In this embodiment, each of the LEDs 20 is located in the reflective slot and each of the photo-reflecting surfaces 31a faces to the LED 20 as to reflect the light emitted from the LED 20.

For the purpose to further increase heat-dissipating speed of the LED 20, several steps are provided in this embodiment and described in detail with the accompanying drawings as follows. In this embodiment, with reference again to FIG. 4C, at least one through hole 131 is formed on the carrier base 13 of the first substrate 10, wherein each of the through holes 131 communicates with the die-attaching region 11 of the first substrate 10 and the bottom surface 12a of the heat-dissipating cavity 12. Besides, each of the heat conductors 70 may further be formed in the through hole 131 of each of the carrier bases 13 and is directly able to touch the LED 20, which enables the heat generated from the LED 20 to be directly conducted to exterior via the heat conductor 70 for rapid heat-dissipation. In another embodiment with reference again to FIG. 5, the package structure further has a Ti layer 50 formed on the upper surface 10a of the first substrate 10 and an Au layer 60 formed on the Ti layer 50 as to increase heat-dissipating efficiency of submount for LED since the Ti layer 50 and the Au layer 60 are the material with high thermal conductive coefficient suitable for heat-dissipation.

Besides, in this embodiment with reference to FIG. 7, the package structure further has a jointing layer 90 formed between the upper surface 10a of the first substrate 10 and the first surface 30a of the second substrate 30. The second substrate 30 may be coupled to the upper surface 10a of the first substrate via the jointing layer 90, wherein the jointing layer 90 could be an adhesion layer when the second substrate 30 is coupled to the upper surface 10a of the first substrate 10 by adhering method, alternatively, the jointing layer 90 could be a metal eutectic jointing layer when using metal eutectic method.

In accordance with the present invention, the difficulty of packaging submount adhering LED 20 and packaging cost can be decreased effectively, the heat-dissipating efficiency of submount for LED 20 is increased practically as well as the LEDs 20 are able to form a line light source by means of optical action of the reflective slots 31, wherein the line light source may be used for replacing the known CCFL(cold cathode fluorescent lamp) which is frequently utilized by LCD(liquid crystal display).

While the present invention has been particularly illustrated and described in detail with respect to the preferred embodiments thereof, it will be clearly understood by those skilled in the art that various changed in form and details may be made without departing from the spirit and scope of the present invention.

What is claimed is:

1. A method for packaging submount adhering LED comprising the steps of:
providing a first substrate, wherein the first substrate has an upper surface, a lower surface opposite to the upper surface and a plurality of die-attaching regions defined on the upper surface;
forming a plurality of heat-dissipating cavities on the lower surface of the first substrate, wherein each of the heat-dissipating cavities corresponds to the die-attaching region and has a bottom surface, there is a carrier base located between the bottom surface and the die-attaching region;
forming a heat conductor in each of the heat-dissipating cavities;
disposing a plurality of LEDs on the die-attaching regions of the first substrate;
providing a second substrate, wherein the second substrate has a first surface facing to the upper surface of the first substrate, a second surface opposite to the first surface and a plurality of reflective slots communicating with the first and second surfaces, each of the reflective slots corresponds to the LED and the die-attaching region; and
coupling the second substrate to the first substrate thereby allowing each of the LEDs to be located in the reflective slot.

2. The method for packaging submount adhering LED in accordance with claim 1, wherein the first substrate is a silicon substrate.

3. The method for packaging submount adhering LED in accordance with claim 1, further comprising a step of forming a Ti layer on the upper surface of the first substrate.

4. The method for packaging submount adhering LED in accordance with claim 3, further comprising a step of forming an Au layer on the Ti layer.

5. The method for packaging submount adhering LED in accordance with claim 1, wherein each of the LEDs is disposed on the carrier base of the first substrate.

6. The method for packaging submount adhering LED in accordance with claim 5, wherein each of the carrier bases has at least one through hole formed thereon, each of the through holes communicates with the die-attaching region of the first substrate and the bottom surface of the heat-dissipating cavity.

7. The method for packaging submount adhering LED in accordance with claim 6, wherein each of the heat conductors is further formed in the through hole of the carrier base.

8. The method for packaging submount adhering LED in accordance with claim 7, wherein each of the heat conductors touches the LED.

9. The method for packaging submount adhering LED in accordance with claim 1, wherein each of the carrier bases has a thickness within a range of 10 to 50 micron.

10. The method for packaging submount adhering LED in accordance with claim 1, further comprising a step of polishing the upper surface of the first substrate to remove the carrier bases and expose the heat conductors on the upper surface.

11. The method for packaging submount adhering LED in accordance with claim 10, wherein each of the LEDs is fixed on the heat conductor.

12. The method for packaging submount adhering LED in accordance with claim 11, further comprising a step of forming a metal solder layer between the LED and the heat conductor as to fix the LED on the heat conductor.

13. A package structure of submount adhering LED comprising:
a first substrate having an upper surface, a lower surface opposite to the upper surface and a plurality of die-attaching regions defined on the upper surface, wherein the lower surface has a plurality of heat-dissipating cavities formed thereon, each of the heat-dissipating cavities corresponds to the die-attaching region and has a bottom surface, there is a carrier base located between the bottom surface and the die-attaching region;
a plurality of heat conductors formed in the heat-dissipating cavities respectively;
a plurality of LEDs disposed on the carrier bases of the first substrate respectively; and
a second substrate coupled to the upper surface of the first substrate and having a first surface facing to the upper surface of the first substrate, a second surface opposite to the first surface and a plurality of reflective slots communicating with the first and second surfaces, wherein each of the reflective slots corresponds to the LED and the die-attaching region, each of the LEDs is located in the reflective slot.

14. The package structure of submount adhering LED in accordance with claim 13, further comprising a Ti layer formed on the upper surface.

15. The package structure of submount adhering LED in accordance with claim 14, further comprising an Au layer formed on the Ti layer.

16. The package structure of submount adhering LED in accordance with claim 13, wherein each of the carrier bases has at least one through hole formed thereon, each of the through holes communicates with the die-attaching region of the first substrate and the bottom surface of the heat-dissipating cavity.

17. The package structure of submount adhering LED in accordance with claim 16, wherein each of the heat conductors is further formed in the through hole of the carrier base.

18. The package structure of submount adhering LED in accordance with claim 17, wherein each of the heat conductors touches the LED.

19. The package structure of submount adhering LED in accordance with claim 13, wherein each of the carrier bases has a thickness within a range of 10 to 50 micron.

20. The package structure of submount adhering LED in accordance with claim 13, further comprising a jointing layer formed between the upper surface of the first substrate and the first surface of the second substrate.
